(19) United States
(12) Patent Application Publication
(10) Pub. No.: US 2025/0038047 A1
(43) Pub. Date: Jan. 30, 2025

(54) CAVITY WITH NEGATIVE SLOPED SIDEWALL OVER GATE AND RELATED METHOD

(71) Applicant: GlobalFoundries Singapore Pte. Ltd., Singapore (SG)

(72) Inventor: Anthony J. Villalon, Singapore (SG)

(21) Appl. No.: 18/359,059

(22) Filed: Jul. 26, 2023

(51) Int. Cl. H01L 21/768; H01L 23/532; H01L 23/535

(52) U.S. Cl. CPC H01L 21/7682; H01L 21/76895; H01L 23/5329; H01L 23/535

(57) ABSTRACT

A semiconductor device includes a transistor including a gate and a dielectric layer over the gate. A cavity is in the dielectric layer above the gate and a portion of the cavity over the gate has a negative sloped sidewall in the dielectric layer. The negative sloped sidewall provides a portion of the cavity having a trapezoidal cross-section having a first width at a lower end adjacent the gate and a second width smaller than the first width at an upper end. The negative sloped sidewall thus places a wider portion of the cavity closer to the gate, which decreases gate-contact capacitance.

### BACKGROUND

The present disclosure relates to semiconductor devices, and more specifically, to a semiconductor device with a cavity, such as an air gap, with a portion having a negative sloped sidewall over a gate. A method of forming the semiconductor device is also provided.

It is a challenge in certain semiconductor devices, such as radio frequency (RF) switches, to control two competing parameters: on-resistance (Rₒₙ) which is the resistance of the switch when power is switched on, and off-state capacitance (C_{off}) which indicates the amount of cross-talk or noise that may occur within the system, i.e., the amount transmitted signals on one circuit creates an undesired effect on another circuit. Rₒₙ is preferred to be as low as possible when the RF switch is on to reduce the power consumption, and C_{off} should be minimized to reduce undesired coupling noise. In conventional semiconductor manufacturing processes, lowering either Rₒₙ or C_{off} results in the opposite effect in the other parameter. Cavities, such as air gaps, in dielectric layer(s) over a transistor's gate are used to lower C_{off}, but additional performance improvements are warranted.

### SUMMARY

A first aspect of the disclosure is directed to a semiconductor device, comprising: a transistor including a gate; a dielectric layer over the gate; and a cavity in the dielectric layer above the gate, a first portion of the cavity over the gate having a negative sloped sidewall in the dielectric layer.

A second aspect of the disclosure includes a semiconductor device, comprising: a transistor including a gate; a dielectric layer over the gate; and a cavity in the dielectric layer above the gate, the cavity including: a first portion having a trapezoidal cross-section having a first width at a lower end of the first portion and a second width smaller than the first width at an upper end of the first portion, and a second portion having a trapezoidal cross-section having the second width at a lower end of the second portion and contiguous with the upper end of the first portion and a third width larger than the second width at an upper end of the second portion.

A third aspect of the disclosure is related to a method of forming a cavity for a semiconductor device, the method comprising: forming a dielectric layer over a transistor including a gate; and forming a cavity in the dielectric layer above the gate, a first portion of the cavity over the gate having a negative sloped sidewall.

Two or more aspects described in this disclosure, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a cross-sectional view of a preliminary structure for a method according to embodiments of the disclosure;

FIG. 2 shows an enlarged cross-sectional view of an illustrative transistor;

FIG. 3 shows a cross-sectional view of a first angled ion implanting to form a damaged area in a first dielectric sub-layer, according to embodiments of the disclosure;

FIG. 4 shows a cross-sectional view of a second angled ion implanting to form the damaged area in the first dielectric sub-layer, according to embodiments of the disclosure;

FIG. 5A shows an enlarged cross-sectional view of the damaged area in the first dielectric sub-layer based on FIG. 4 and according to embodiments of the disclosure;

FIGS. 5B-D show perspective views of illustrative shapes of damaged area(s) from one or more ion implantation steps, according to embodiments of the disclosure;

FIG. 6 shows a cross-sectional view of an optional, third ion implanting to form the damaged area in the first dielectric sub-layer, according to other embodiments of the disclosure;

FIG. 7 shows an enlarged cross-sectional view of the damaged area in the first dielectric sub-layer based on FIG. 6, according to other embodiments of the disclosure;

FIG. 8 shows a cross-sectional view of forming a second dielectric sub-layer over the damaged area of FIG. 6, according to embodiments of the disclosure;

FIG. 9 shows a cross-sectional view of forming an opening for a cavity in a dielectric layer using the damaged area of FIG. 6, according to embodiments of the disclosure;

FIG. 10 shows a cross-sectional view of a semiconductor device such as a radio frequency SOI switch with a cavity over a transistor gate thereof, according to embodiments of the disclosure;

FIG. 11 shows a cross-sectional view of forming a second dielectric sub-layer over the damaged area of FIG. 4, according to other embodiments of the disclosure;

FIG. 12 shows a cross-sectional view of forming an opening for a cavity in a dielectric layer using the damaged area of FIG. 4, according to other embodiments of the disclosure;

FIG. 13 shows a cross-sectional view of a semiconductor device such as a radio frequency SOI switch with a cavity over a transistor gate thereof, according to other embodiments of the disclosure;

FIG. 14 shows an enlarged cross-sectional view of the cavity over the transistor gate in FIG. 10 according to embodiments of the disclosure;

FIG. 15 shows an enlarged cross-sectional view of the cavity over the transistor gate in FIG. 13, according to embodiments of the disclosure;

FIG. 16 shows an enlarged cross-sectional view of the cavity over the transistor gate, according to alternative embodiments of the disclosure; and

FIG. 17 shows an enlarged cross-sectional view of the cavity over the transistor gate, according to alternative embodiments of the disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on,” “directly contacting” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (A) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

The present disclosure relates to methods of forming semiconductor devices including a cavity, such as an air gap, over a gate for reducing the capacitance between the gate and adjacent wires, contacts, and vias used to contact the source and drain of the transistor. This capacitance reduction may decrease the off-state capacitance of the transistor when it is used in such applications as radio frequency (RF) switches in semiconductor-on-insulator (SOI) substrates or bulk (non-SOI) substrates. Use of a cavity over a gate according to the various embodiments of the disclosure provides a mechanism to reduce off-capacitance of any device using it by controlling one of the main contributors of intrinsic field effect transistor (FET) capacitance: the effective dielectric constant of the dielectric material of the contact or local interconnect layer and the first metal layer. Embodiments of the disclosure, more particularly, include a semiconductor device including a transistor including a gate and a dielectric layer over the gate. A cavity is in the dielectric layer above the gate and a portion of the cavity over the gate has a negative sloped sidewall in the dielectric layer. The negative sloped sidewall places a wider portion of the cavity closer to the gate, which further decreases gate-contact capacitance. While the teachings of the disclosure will be described with regard to an SOI substrate and relative to an RF switch, it will be understood that the embodiments can be applied to various alternative semiconductor devices such as but not limited to low noise amplifiers (LNA) and power amplifiers. Further, the teachings may be applied to different substrates, such as a bulk substrate.

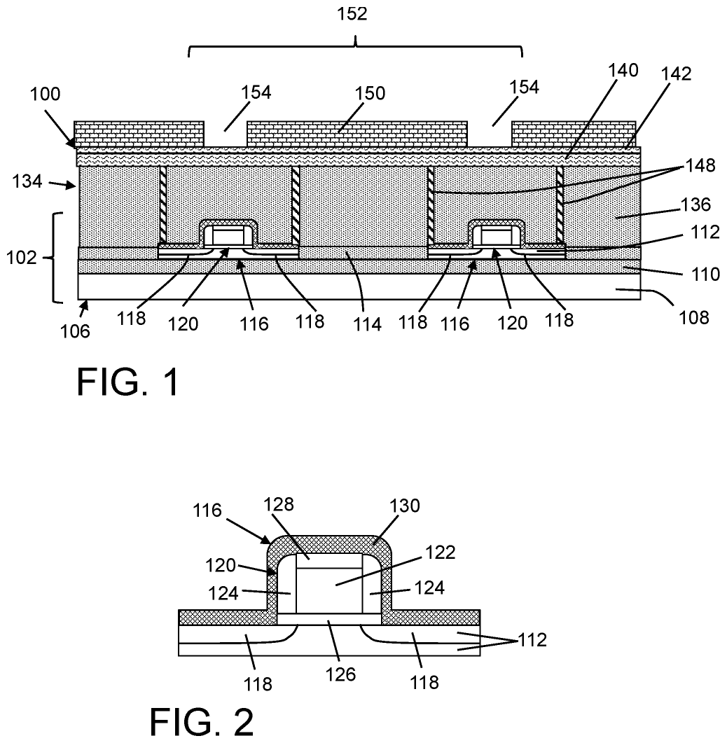

Referring to FIGS. 1 and 3-13, cross-sectional views of a method of forming a cavity, such as an air gap, for a semiconductor device according to embodiments of the disclosure are illustrated. More particularly, as will be described, FIGS. 1 and 3-13 collectively show forming a dielectric layer (including two dielectric sub-layers) over a transistor including a gate and forming a cavity in the dielectric layer above the gate with a first portion of the cavity over the gate having a negative sloped sidewall.

FIG. 1 shows a preliminary structure 100 after forming an interconnect layer over a transistor, the interconnect layer including a first dielectric sub-layer over the transistor. More particularly, FIG. 1 shows a preliminary structure 100 after formation of a device layer 102. Device layer 102 is illustrated as including a semiconductor-on-insulator (SOI) substrate 106 including a semiconductor substrate 108 with an insulator layer 110 thereover and a semiconductor-on-insulator (SOI) layer 112 over insulator layer 110. Substrate 108 and SOI layer 112 may include any semiconductor material described herein. Furthermore, a portion or entire semiconductor substrate 108 and/or SOI layer 112 may be strained. For example, SOI layer 112 may be strained. SOI layer 112 may be segmented by shallow trench isolations (STI) 114. Insulator layer 110 may include any appropriate dielectric material for the application desired, e.g., silicon oxide (SiOₓ) or (less commonly) sapphire. Insulator layer 110 and/or STI 114 may also include the same material, such as silicon dioxide or any other interlayer dielectric material described herein.

Device layer 102 also includes a number of transistors 116 formed therein. (In the drawings, one or two transistors 116 may be shown for clarity of illustration-any number of transistors and cavities can be used). Each transistor 116 may include any now known or later developed transistor structure such as doped source/drain regions 118 in SOI layer 112 having a transistor gate 120 thereover and therebetween. FIG. 2 shows an enlarged cross-sectional view of an illustrative transistor 116 and transistor gate 120. Each gate 120 may include, among other structures, a gate body 122 of polysilicon or a metal gate conductor (commonly referred to collectively as “PC”), sidewall spacers 124 adjacent gate body 122, a gate dielectric 126 under gate body 122, a silicide layer 128 over gate body 122 (i.e., a silicon-metal alloy), and an etch stop layer 130 over silicide layer 128 and/or spacers 124. Sidewall pacers 124 may include any now known or later developed spacer material such as silicon nitride (Si₃N₄), and gate dielectric 126 may include any now known or later developed gate dielectric material such as: hafnium silicate (HfSiO), hafnium oxide (HfO₂), zirconium silicate (ZrSiOₓ), zirconium oxide (ZrO₂), silicon oxide (SiO₂), silicon nitride (Si₃N₄), silicon oxynitride (SiON), high-k material or any combination of these materials. Etch stop layer 130 may include any now known or later developed material, such as silicon nitride. Etch stop layer 130 is laterally adjacent to sidewall spacer 124. Silicide layer 128 may include any now known or later developed silicon-metal alloy material, e.g., titanium, nickel, cobalt, etc. As understood, each gate 120 may run into, out of, or across the page as illustrated. Each transistor 116 may be formed using any now known or later developed semiconductor fabrication techniques, e.g., material deposition, photolithographic patterning and etching, doping, etc. As such techniques are well understood those skilled in the art, no further details are necessary.

Referring again to FIG. 1, preliminary structure 100 also includes an interconnect layer 134 over transistor 116, e.g., a zero via (V0) or local interconnect layer. Local interconnect layer 134 includes a first dielectric sub-layer 136 over transistor 116. FIG. 1 shows forming first dielectric sub-layer 136 over gate 120. The term “sub-layer” is used herein to differentiate between two layers that will combine to form a “dielectric layer” in which a cavity 180 (FIGS. 10, 13-17) is provided. First dielectric sub-layer 136 may include an interlayer dielectric material such as but not limited to: silicon nitride (Si₃N₄), silicon oxide (SiO₂), fluorinated SiO₂ (FSG), hydrogenated silicon oxycarbide (SiCOH), porous SiCOH, boro-phospho-silicate glass (BPSG), silsesquioxanes, carbon (C) doped oxides (i.e., organosilicates) that include atoms of silicon (Si), carbon (C), oxygen (O), and/or hydrogen (H), other low dielectric constant (<3.9) material, or layers thereof. First dielectric sub-layer 136 may also include a respective cap layer 140, 142 at an upper surface thereof. Each cap layer 140, 142 may include one or more layers of, for example, a silicon oxide layer and an etch stop layer, formed from silicon nitride (nitride), silicon carbo nitride (SiCN), etc., as known in the art. As understood, various other forms of cap layers may also be employed. Further, it is emphasized that while cap layers 140, 142 are illustrated as identical, they can be different materials, thicknesses, etc.

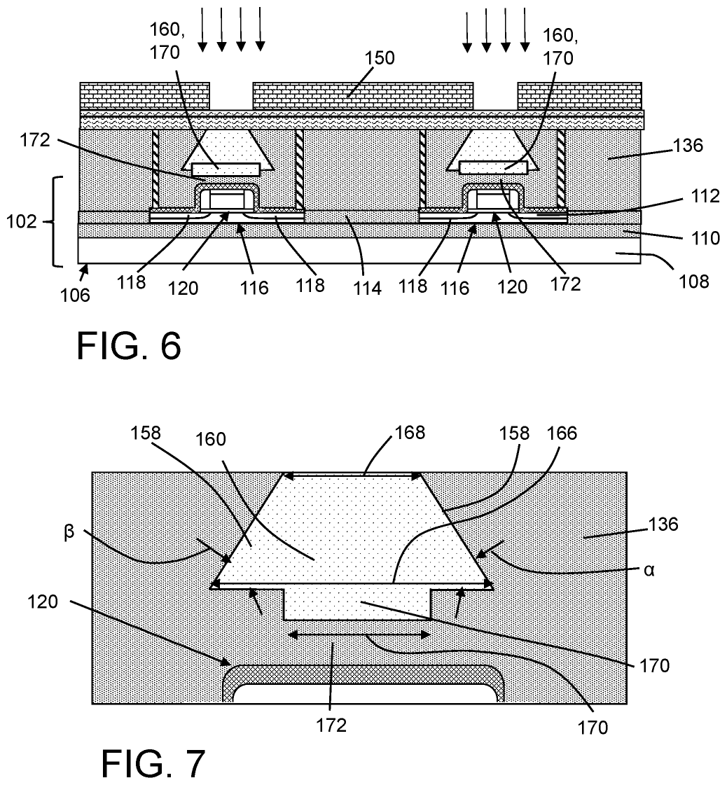

For purposes of description, local interconnect layer 134 is illustrated as including a plurality of contacts 148 at this stage of processing. It is emphasized, however, that contacts 148 can be formed at a later stage of the processing, i.e., after, as will be described, formation of damaged area 160 (FIGS. 4 and 6). Any number of contacts 148 may extend through first dielectric sub-layer 136 of contact or local interconnect layer 134 to various parts of device layer 102. In the example shown, contacts 148 extend to source/drain regions 118 of transistors 116. Other contacts (not shown) may extend to gate 120. As understood, each contact 148 may include a conductor of tungsten (W) within a metal liner of titanium nitride (TiN). Typically, contacts 148 extend mostly vertically within the semiconductor device to connect conductors in layers thereof, i.e., vertically on page as illustrated. First dielectric sub-layer 136 and contacts 148 may be formed using any now known or later developed semiconductor fabrication techniques, e.g., photolithographic patterning and etching, material deposition, planarization, etc. As such techniques are well understood those skilled in the art, no further details are necessary.

FIGS. 1 and 3-4 show forming a damaged area in first dielectric sub-layer 136 over gate 120. Starting with FIG. 1, a first mask 150 having a doping pattern 152 therein is formed. For purposes of description, first mask 150 may be referred to as a “doping mask.” Doping pattern 152 may include openings 154 with a pattern to form doped regions where desired. Doping pattern 152 exposes portions of first dielectric sub-layer 136 over gates 120 of transistors 116 in device layer 102. Openings 154 may also extend into and out of the page. Mask 150 may include any now known or later developed masking material, e.g., a photoresist. The term “mask” may be given to a layer of material which is applied over an underlying layer of material, and patterned to have openings, so that the underlying layer can be processed where there are openings. Common masking materials are photoresist (resist) and nitride. Nitride is usually considered to be a “hard mask.” Mask may include a developable organic planarization layer (OPL) on the layer to be etched, a developable anti-reflective coating (ARC) layer on the developable OPL, and a photoresist mask layer on the developable ARC layer. Masks may be removed using any known removal process appropriate for the mask material, e.g., a wet etch for hard nitride mask or an ashing process (oxygen dry strip process) for a soft resist-based mask. Mask 150 is patterned and etched in a conventional fashion to create doping pattern 152 therein.

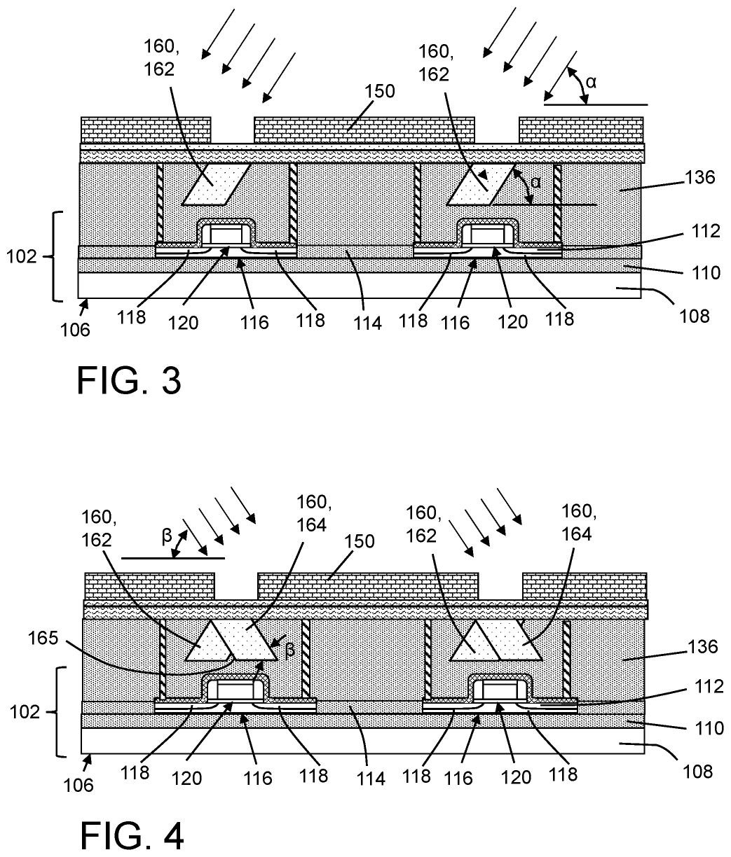

FIGS. 3-4 show cross-sectional views of using first mask 150 having doping pattern 152 (FIG. 1) to form a damaged area 160 in first dielectric sub-layer 136 over gate 120. As will be further described, damaged area 160 has a portion over gate 120 having negative sloped sides 158, i.e., the sides slope inwardly to form a narrower upper end and a wider lower end. Forming damaged area 160 in first dielectric sub-layer 136 over gate 120 includes performing an angled ion implantation. The angled ion implantation may include a plurality of ion implantation steps. (Each new damaged area created by a respective ion implantation is shown with a solid line around it for clarity but is thereafter shown as a merged area with any previously-formed damaged area). FIG. 3 shows a first ion implanting of a dopant (arrows) at a first angle α into first dielectric sub-layer 136 over gate 120, forming a first damaged area 162. As will be further described, first angle α may match a first side of the eventually formed negative sloped sidewall of the cavity. FIG. 4 shows a second ion implanting of a dopant (arrows) at a second angle β into first dielectric sub-layer 136 over gate 120, forming a second damaged area 164. As will be further described, second angle β may match a second side of the eventually formed negative sloped sidewall of the cavity. First and second angles α, β may be the same or different. Collectively, first and second damaged areas 162, 164 form damaged area 160. For purposes of this disclosure, the “damaged area” is an area that is chemically and/or structurally different from the adjacent area of first dielectric sub-layer 136 not implanted with the dopant (i.e., the undamaged area). The dopant implanted may be any dopant capable of damaging first dielectric sub-layer 136, making it faster to etch than undamaged portions of first dielectric sub-layer 136. In certain embodiments, a dopant that does not otherwise change electrical properties of adjacent material, such as argon or germanium, may be used. However, other dopants are also possible. The ion implanting strength and dosage may vary depending on the material of first dielectric sub-layer 136, whether contacts 148 and/or cap layers 140, 142 are present, and the desired depth of penetration for damaged area 160. In terms of depth of penetration, damaged area 160 does not reach gate 120, i.e., etch stop layer 130 (FIG. 2). In any event, as will be described herein, the ion implanting creates damaged area 160 that will etch faster than the undamaged area of first dielectric sub-layer 136. A notch 165 (shown in left side of FIG. 4 only) of undamaged dielectric sub-layer may exist at a lower surface between first and second damaged areas 162, 164, but generally damage area 160 has a (merged) trapezoidal cross-sectional shape. Notch 165 is typically removed in subsequent processing.

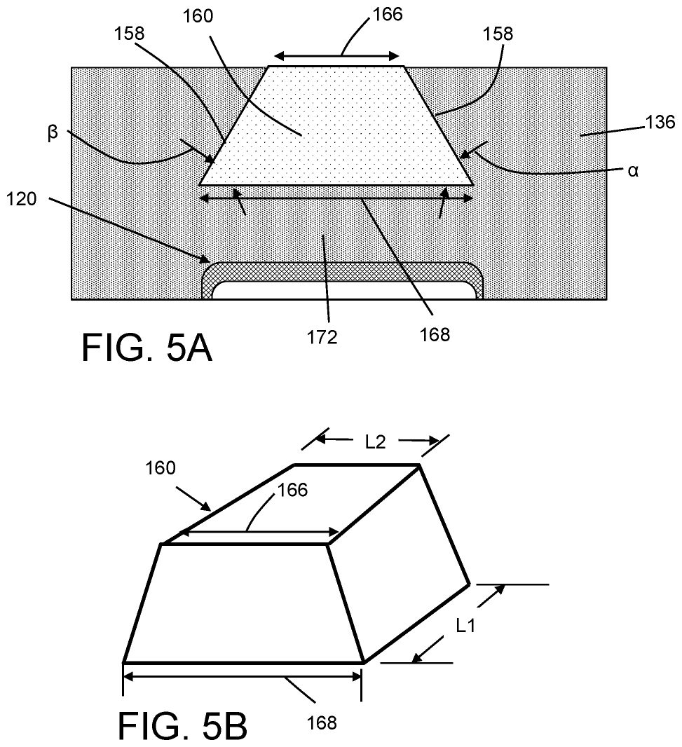

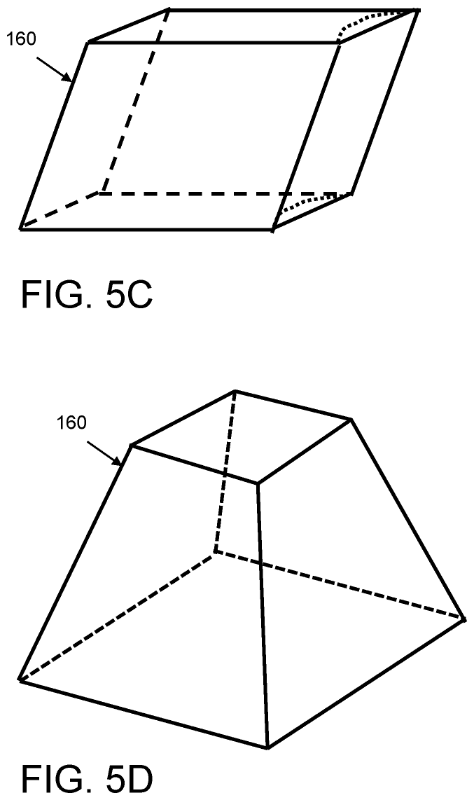

FIG. 5A shows an enlarged cross-sectional view of damaged area 160. Damaged area 160, based on the angles α, β of the ion implantations, has negative slope sides 158, i.e., sides 158 slope inwardly to form a narrower upper end 166 and a wider lower end 168. Sides 158 can be generally straight. Consequently, damaged area 160 has a generally trapezoidal shape with narrower upper end 166 and wider lower end 168.

It will be recognized that where openings 154 (FIG. 1) extend into and out of the page, damage area 160 may also extend into and out of the page, creating a linear damaged area 160 having the trapezoidal cube shape shown in FIG. 5B. A length L1 can be determined based on opening 154 and ion implantation characteristics. Alternatively, opening 154 may not have a significant linear extent, and may have, for example, a square cross-sectional opening, i.e., with length L1 similar to length L2 (the latter length L2 corresponding to upper end 166 of trapezoid). A circular cross-sectional opening 154 can provide similarly shaped damaged area 160 with curved edges.

Each individual angled ion implantation generates a damaged area 162, 164 that is generally parallelepiped shaped, as shown in FIG. 5C for the first ion implantation in FIG. 3. The parallelepiped can have linear edges or curved edges (dashed lines) depending on the shape of openings 154. In other embodiments, additional ion implantations similar to that shown in FIGS. 3 and 4 may also be carried out in different directions. For example, a wafer upon which the method is being performed (for any number of IC dies) can be turned, for example, 90 degrees, and the two angled ion implantations repeated. In this example, damaged area 160 may have a shape approximating a truncated pyramid, as shown in FIG. 5D, depending on how much the individual damages areas merge together. As will be described, first portion 252 (FIGS. 10, 13-17) of cavity 180 (FIGS. 10, 13-17) that is eventually formed from damaged area 160 may have any of the shapes shown in FIGS. 5A-D.

FIG. 6 shows a cross-sectional view of an optional step. In FIG. 6, forming damaged area 160 may optionally further include a third ion implanting of a dopant (arrows) at an angle perpendicular to first dielectric sub-layer 136 over gate 120. The third ion implanting forms an extension 170 on damaged area 160 in FIGS. 4 and 5A. The dopant implanted in FIG. 6 may be the same as that used in FIGS. 3-4; however, a different dopant may be used if desired. The ion implanting strength and dosage may vary depending on the material of first dielectric sub-layer 136, whether contacts 148 and/or cap layers 140, 142 (FIG. 1) are present, and the desired depth of penetration. In particular, the depth of ion implanting in FIG. 6 can be precisely controlled to control a depth of damaged area 160 in first dielectric sub-layer 136 over gate 120. FIG. 7 shows an enlarged cross-sectional view of damaged area 160. A portion 172 of first dielectric sub-layer 136 that is undamaged may remain between damaged area 160, i.e., extension 170, and gate 120. Damaged area 160 in FIG. 7 also includes extension 170. Otherwise, damaged area 160 is similar to that shown and described relative to FIGS. 5A-D.

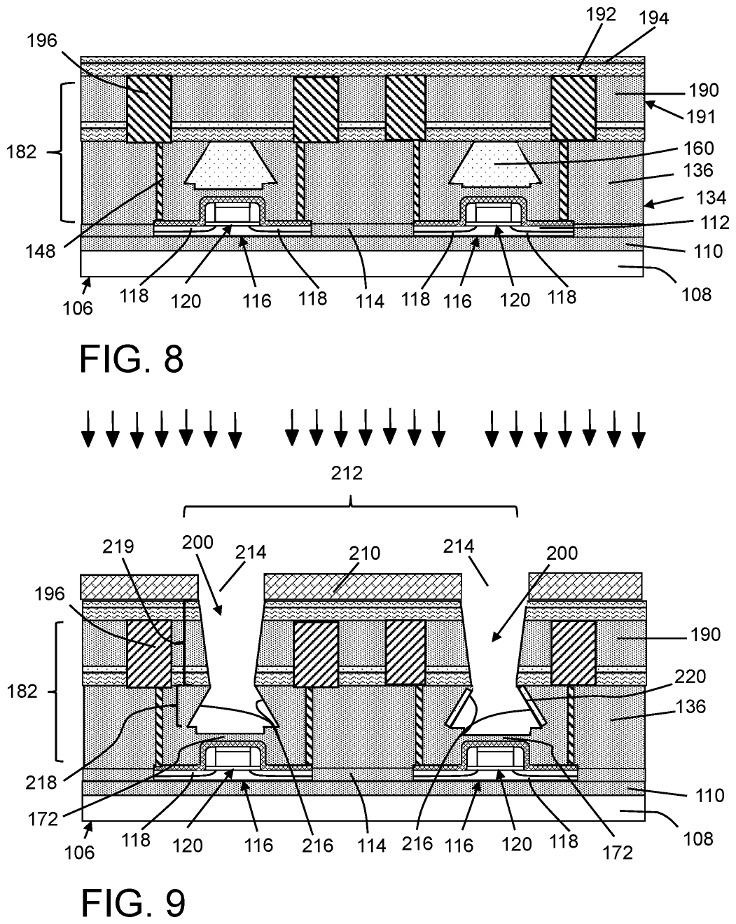

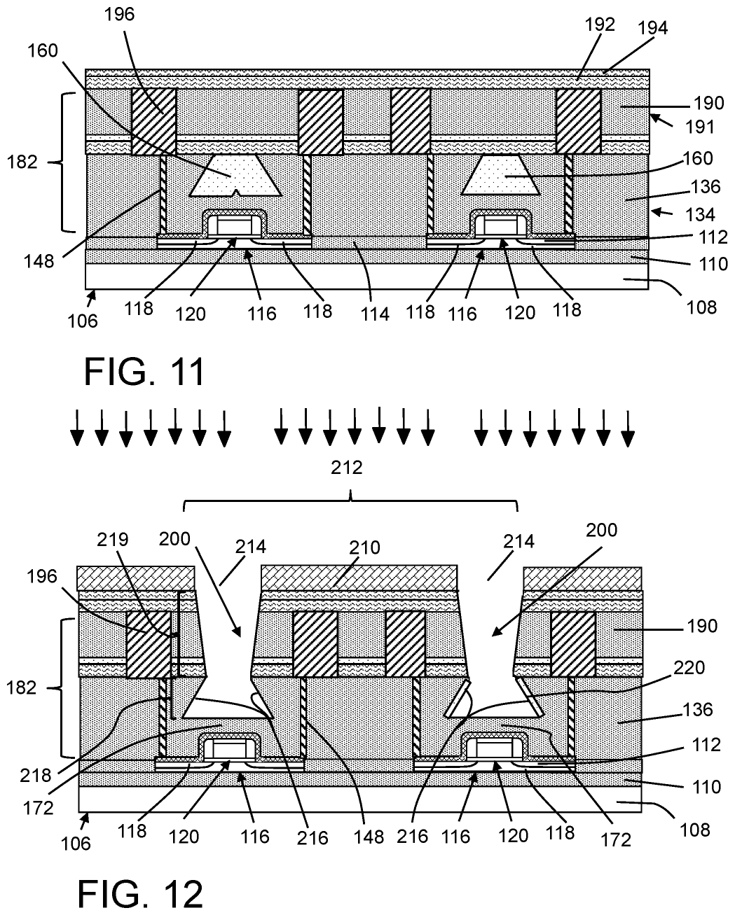

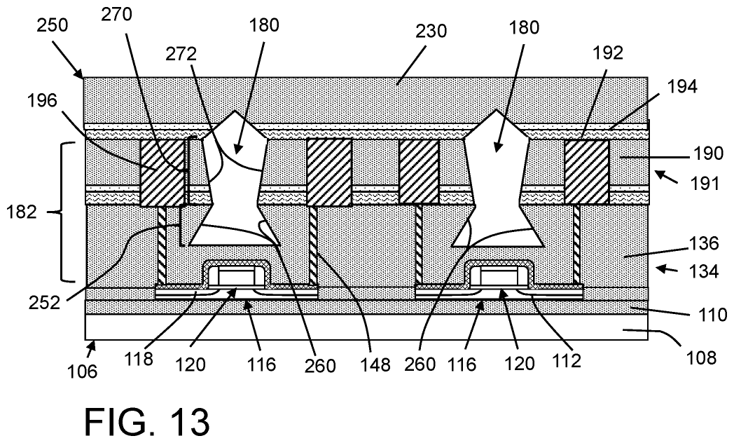

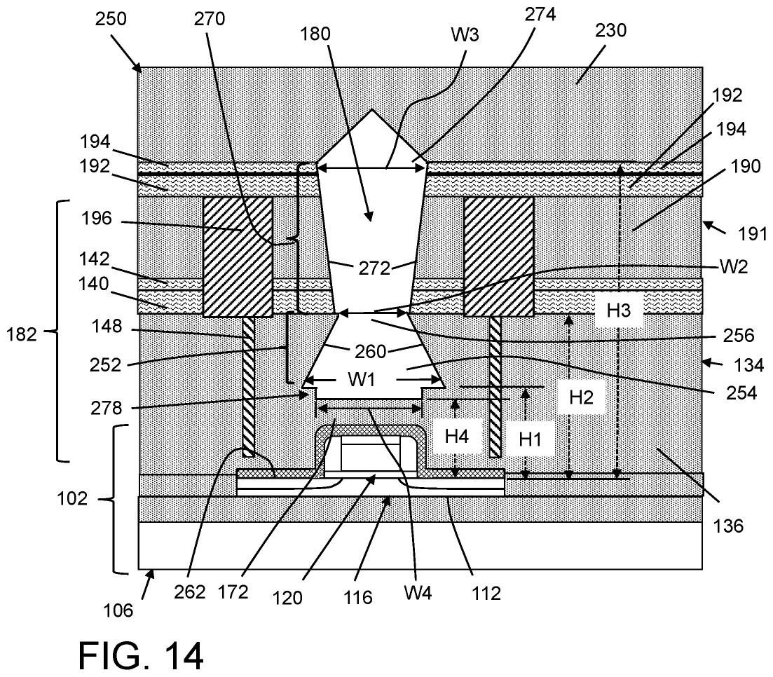

FIGS. 8-10 show forming a cavity 180 (FIG. 10) in a dielectric layer 182 (FIGS. 8-10) above gate 120 according to the FIGS. 6 and 7 embodiments, i.e., with extension 170 on damaged area 160, and FIGS. 11-13 show forming cavity 180 (FIG. 13) in dielectric layer 182 (FIGS. 11-13) above gate 120 according to the FIGS. 4 and 5 embodiments, i.e., without extension 170.

FIGS. 8 and 11 show forming a second dielectric sub-layer 190 over first dielectric sub-layer 136, forming (combined) dielectric layer 182. Second dielectric sub-layer 190 may include the same materials as first dielectric sub-layer 136, e.g., silicon oxide. Second dielectric sub-layer 190 may also include any form of cap layer(s) 190, 194 at an upper surface thereof. Each cap layer 192, 194 may include one or more layers of, for example, a silicon oxide layer and an etch stop layer, formed from silicon nitride (nitride), silicon carbo nitride (SiCN), etc., as known in the art. As understood, various other forms of cap layers may also be employed. Further, it is emphasized that while cap layers 192, 194 are illustrated as identical, they can be different materials, thicknesses, etc.

Where first dielectric sub-layer 136 already includes contacts 148, wires 196 may be formed in second dielectric sub-layer 190 at this stage. Second dielectric sub-layer 190 may include any number of wires 196 extending through second dielectric sub-layer 190 to various contacts 148, among other things. Hence, second dielectric sub-layer 190 may provide a first metal layer 191. In the example shown, wires 196 couple to contacts 148. Other wires (not shown) may extend to other parts of the semiconductor device. As understood, each wire 196 may include a conductor such as aluminum or copper, within a refractory metal liner of tantalum nitride (TaN); however, other refractory metals such as tantalum (Ta), titanium (Ti), ruthenium (Ru), tungsten (W), iridium (Ir), rhodium (Rh) and platinum (Pt), etc., or mixtures of thereof, may also be employed. In contrast to contacts 148 metal wires 196 extend mostly horizontally or laterally in a layer within the semiconductor device to connect contacts 148 therein, i.e., into, out of, or across a page as illustrated. In this manner, a first metal layer 191 may include metal wire(s) 196 extending laterally parallel to transistor gate 120 in device layer 102, i.e., vertically above but parallel to transistor gate 120. Second dielectric sub-layer 190 can be formed using any now known or later developed semiconductor fabrication techniques, e.g., material deposition, photolithographic patterning and etching, planarization, etc. Although contacts 148 and wires 196 are shown in the drawings as single damascene levels, if contacts 148 were not previously formed (FIG. 1), they could both be formed at this stage using dual damascene levels containing refractory metal lined copper or tungsten, as known in the art. In this case, cap layer 140, 142 (labeled in FIG. 1) would not be present and dielectric sub-layers 136, 190 would be in direct contact (forming dielectric layer 182). As such techniques are well understood those skilled in the art, no further details are necessary.

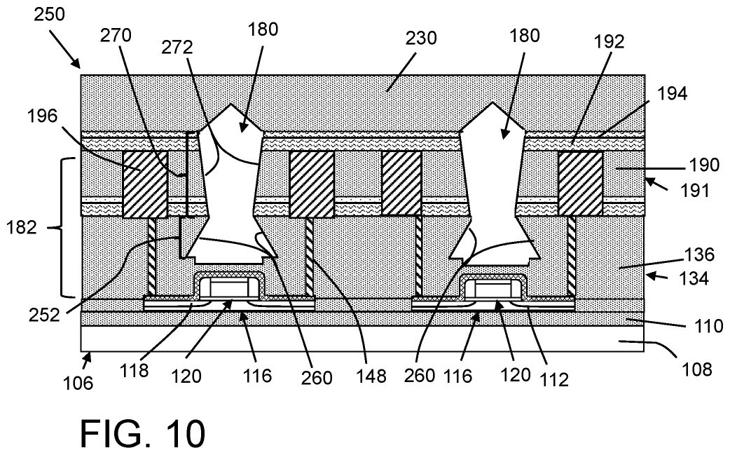

FIGS. 9 and 12 show forming an opening 200 into dielectric layer 182. More particularly, FIGS. 9 and 12 show, using a second mask 210 having air gap pattern 212, forming opening 200 into dielectric layer 182 over transistor 116, e.g., by etching. Mask 210 is patterned and etched in a conventional fashion to create openings 214 therein. Mask 210 may be formed, for example, post first metal layer damascene planarization, e.g., via chemical mechanical polishing (CMP), and may include any now known or later developed masking material.

As shown in FIGS. 9 and 12, opening 200 extends into dielectric layer 182, which includes second dielectric sub-layer 190 and first dielectric sub-layer 136. More particularly, opening 200 extends through second dielectric sub-layer 190 into first dielectric sub-layer 136 and extends into damaged area 160. As noted, damaged area 160 etches faster than undamaged areas of dielectric layer 182, i.e., dielectric sub-layers 136, 190. More specifically, opening 200 removes most, if not all, of damaged area 160. In some cases, as shown for the right-side opening 200 only in FIGS. 9 and 12, some residual layer 220 of damage area 160 may remain adjacent opening 200. In any event, opening 200 has a unique shape. More particularly, as a result of damage area 160 having negative sloped sides 158 (FIGS. 5A and 7), opening 200 has negative sloped sidewalls 216 in a lower portion 218 thereof, i.e., the sidewalls slope inwardly to form a narrower upper end and a wider lower end for first portion 218 of opening 200 near gate 120. In contrast, an upper portion 219 of opening 200 has positive sloped sidewalls (not numbered for clarity in FIGS. 9 and 12 (272 in later drawings)), i.e., the sidewalls slope outwardly to form a narrower lower end and a wider upper end for upper portion 219 of opening 200.

In FIGS. 9 and 12, the etching (indicated by arrows) may include a reactive ion etch (RIE) or any other form of etching that is selective for the damaged area over the undamaged area and capable of forming opening 200. Opening 200 is “above the transistor gate,” meaning opening 200 and/or any cavity/air gap formed therewith, overlaps transistor gate 120 in any fashion. With regard to opening 200 depth, etching is stopped before it removes portion 172 of dielectric layer 182. That is, the etching does not expose etch stop layer 130 (FIG. 2) or silicide layer 128 (FIG. 2) by not extending through portion 172 of dielectric layer 182 above gate 120. Rather, portion 172 over gate 120 (FIG. 2) that is undamaged by the ion implanting (FIGS. 3, 4, 6) remains after opening 200 is formed. The etching is otherwise controlled to select the depth of opening 200, e.g., through etching strength, duration, etc.

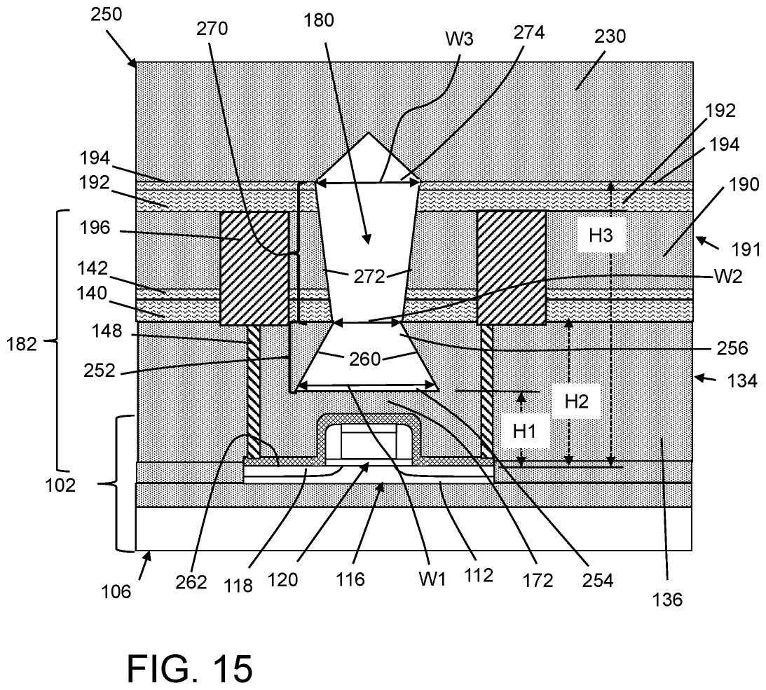

FIGS. 10 and 13 show forming cavity 180, e.g., an air gap, over gate 120 by depositing a capping layer 230 to seal opening 200. Prior to forming cavity 180, mask 210 (FIGS. 9 and 12) may be removed using any now known or later developed removal process appropriate for the mask material, e.g., a wet etch for hard nitride mask or an ashing process (oxygen dry strip process) for a soft resist-based mask. As noted, FIG. 10 shows cavity 180 relative to the FIGS. 4-5A embodiments, and FIG. 13 shows cavity 180 relative to the FIGS. 6-7 embodiments. As shown, cavity 180 is vertically aligned with gate 120, although perfect alignment is not necessary in all cases. Capping layer 230 may include any dielectric material capable of sealing opening 200 (FIGS. 9 and 12) and acting as an ILD for a first via layer to be formed therein. In one embodiment, capping layer 230 may include chemical vapor deposited (CVD) dielectric. In another embodiment, capping layer 230 may include a plasma-enhanced chemical vapor deposition (PECVD) silane oxide. PECVD silane oxide may be chosen because it has very poor step coverage, resulting in a larger cavity volume. In other embodiments, capping layer 230 may include a thin silicon nitride layer with an ILD oxide, such as a PECVD TEOS-based, PVD, or similar oxide (individual layers not shown for clarity). Although not shown, in some cases, edges of cap layer(s) 192, 194 of first metal layer 191 may act to pinch opening 200 (FIGS. 10 and 12) to assist in closing cavity 180. Cavity 180 is a sealed cavity and may include a gas, such as air or an inert gas, or a vacuum therein. Cavity 180 does not expose any contact 148 or metal wire 196, i.e., dielectric sub-layers 136, 190 about cavity 180 cover any conductive wire 196 in first metal layer 191 or any conductive contact 148 in local interconnect layer 134. Cavity 180 may have any lateral layout of opening 200, as described herein. As understood in the art, contacts (not shown) to another metal layer may be formed in capping layer 230, using any conventional or later developed technique. As will be further described further relative to the enlarged views of FIGS. 14 and 15, forming a first portion 252 of cavity 180 includes forming the first portion of the cavity to have a first section 254 (lower section) having a first width W1 and a second section 256 (upper section) having a second width W2 less than first width W1. As shown, first section 254 is closer to gate 120 than second section 256 and negative sloped sidewalls 260 connect first section 254 and second section 256.

Referring to FIGS. 10 and 13-15, a semiconductor device 250 according to embodiments of the disclosure will now be described in more detail. FIG. 14 shows an enlarged cross-sectional view of semiconductor device 250 of the FIG. 10 embodiment, and FIG. 15 shows an enlarged cross-sectional view of semiconductor device 250 of the FIG. 13 embodiment.

Semiconductor device 250 may include transistor 116 including gate 120. Transistor 116 may also include S/D regions 118 in device layer 102 (FIG. 9-10). Transistor 116 can take the form of any now known or later developed complementary metal-oxide semiconductor (CMOS) field effect transistor (FET). Gate 120 may include gate body 122 and sidewall spacer 124 adjacent gate body 122. Gate 120 may also include silicide layer 128 over gate body 122 and etch stop layer 130 over silicide layer 128 and sidewall spacer 124.

Semiconductor device 250 also includes dielectric layer 182 over gate 120. Dielectric layer may include first dielectric sub-layer 136 and second dielectric sub-layer 190, as described herein. First dielectric sub-layer 136 and second dielectric sub-layer 190 may include contacts 148 and wires 196 therein, i.e., formed before or after forming damaged area 160 (FIGS. 4, 5A-D, 6 and 7). Dielectric layer 182 may include one or more interconnect layers, for example, a local interconnect layer and a first metal layer. Dielectric layer 182 can also include additional layers, not shown.

Semiconductor device 250 also includes cavity 180 in dielectric layer 182 over gate 120. Cavity 180 is a sealed cavity and may include a gas (e.g., air or an inert gas) or a vacuum therein. In certain embodiments, cavity 180 can be an air gap. A first portion 252 of cavity 180 over gate 120 has negative sloped sidewalls 260. With reference to FIGS. 14 and 15, negative sloped sidewalls 260 are angled inwardly, resulting in first portion 252 of cavity 180 including first section 254 (lower section) having first width W1 and second section 256 (upper section) having second width W2 less than first width W1. As shown, first section 254 is closer to gate 120 than second section 256 and negative sloped sidewalls 260 connects first section 254 and second section 256. More particularly, as also shown in FIGS. 14 and 15, first portion 252 of cavity 180 in dielectric layer 182 has a first width W1 at a first height H1 and a second width W2 less than first width W1 at a second height H2. First height H1 is closer to gate 120 than second height H2 and negative sloped sidewalls 260 extends between first height H1 and second height H2. Heights H1 and H2 (and any other heights described herein) can be identified relative to, for example, an upper surface 262 of SOI layer 112. In view of the foregoing, first portion 252 has a trapezoidal cross-section having first width W1 at a lower end (first section 254) of first portion 252 and second width W2 smaller than first width W1 at an upper end (second section 256) of first portion 252. The angle of first and second ion implantations (FIGS. 3 and 4) and the characteristics of the ion implantations (e.g., strength/energy, dosage, duration, dopant concentration, dopant type, etc.) controls the widths and depth of first portion 252.

Cavity 180 also has a second portion 270 in dielectric layer 182 over and contiguous with first portion 252 thereof. Second portion 270 has positively angled sidewalls 272, i.e., they are angled outwardly and diverge from a lower end to an upper end. More particularly, second portion 270 has second width W2 at second height H2 and a third width W3 larger than second width W2 at a third height H3. Second height H2 is lower than third height H3 and is between first height H1 and third height H3. In view of the foregoing, second portion 270 in dielectric layer 182 has a trapezoidal cross-section having second width W2 at a lower end of second portion 270 contiguous with upper end (second section 256) of first portion 252 and has third width W3 larger than second width W2 at an upper end 274 of second portion 270. The trapezoidal cross-section of second portion 270 can be more elongated vertically compared to that of first portion 252. (Note, while height H3 is shown at a particular vertical location on second portion 270, height H3 can be at any vertical location along a height of second portion 270 other than a lowermost extent of second portion 270 of cavity 180, i.e., almost any vertical location of second portion 270 will have a larger width W3 than second width W2).

As shown in FIG. 14, cavity 180 may also optionally have a third portion 278 in dielectric layer 182 under and contiguous with first portion 252. Third portion 278 has a fourth width W4 smaller than first width W1 at a fourth height W4 below first height H1. Fourth height H4 is distanced from gate 120 by portion 172 of dielectric layer 182, i.e., first dielectric sub-layer 136, separating third portion 278 of cavity 180 from gate 120. Third portion 278 in dielectric layer 182 may have a rectangular cross-section having fourth width W4 smaller than first width W1 of first portion 252 and contiguous with the lower end (first section 254) of first portion 252.

Portion 172 of dielectric layer 182 is positioned between cavity 180 and gate 120. Thus, portion 172 of dielectric layer 182 defines a lower surface or bottom of cavity 180. Portion 172 of dielectric layer 182 (which is for local interconnect layer 134 of semiconductor device 250) provides a lower surface or a bottom of cavity 180 and is in direct contact with gate 120. Dielectric layer 182 is never entirely removed from over gate 120. Hence, dielectric layer 182 is devoid of seams or other discontinuities over gate 120. A distance between the bottom of cavity 180 and gate 120 (including, as shown in FIG. 2, silicide layer 128 and etch stop layer 130) or the thickness of portion 172, can be controlled by controlling the characteristics of the relevant ion implantation(s), e.g., strength/energy, dosage, duration, dopant concentration, dopant type, etc. With regard to the FIGS. 6, 7, 10 and 14 embodiments, controlling third ion implantation (FIG. 6) controls a distance between third portion 278 of cavity 180 and gate 120. In contrast, with regard to the FIGS. 4, 5, 13 and 15 embodiments, controlling the first and second ion implantations (FIGS. 3 and 4) controls a distance between first portion 252 of cavity 180 and gate 120.

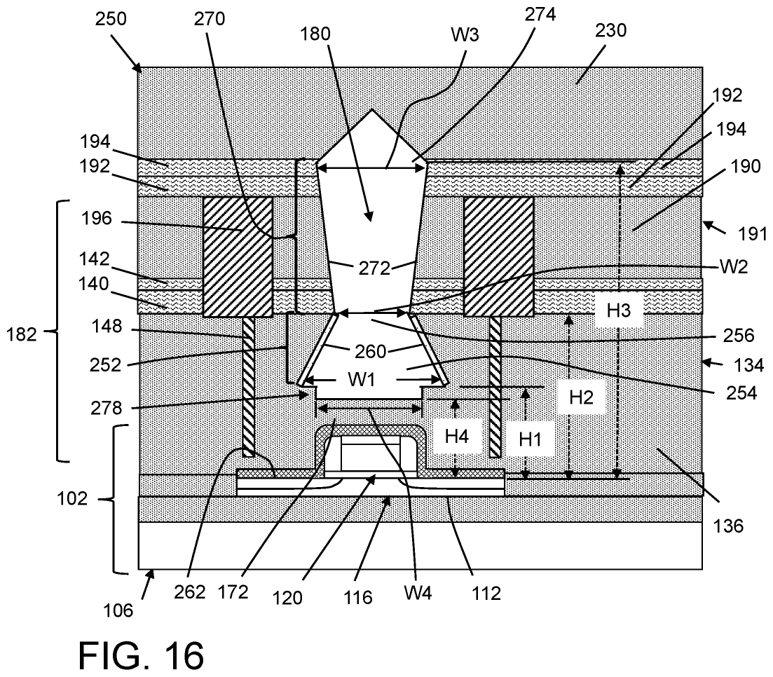

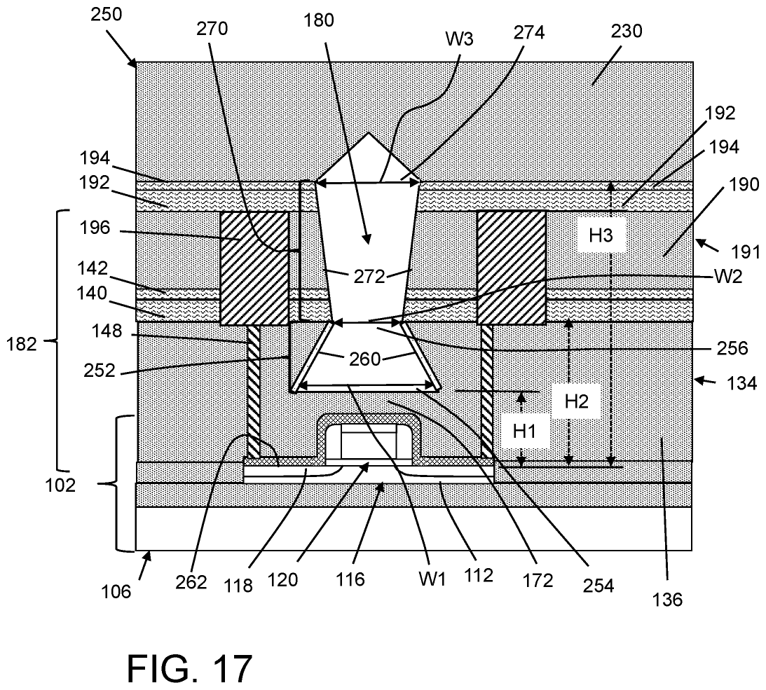

FIG. 16 shows an enlarged cross-sectional view of semiconductor device 250 similar to the FIGS. 10 and 14 embodiments, and FIG. 17 shows an enlarged cross-sectional view of semiconductor device 250 similar to the FIGS. 13 and 15 embodiments, according to alternative embodiments. As shown in FIGS. 16 and 17, in certain embodiments, some of damaged area 160 (FIGS. 9 and 12, right side) may remain on negative sloped sidewalls 260 of first portion 252 in dielectric layer 182 after formation of opening 200 (FIGS. 9 and 12). Consequently, as shown in FIGS. 16 and 17, negative sloped sidewalls 260 of cavity 180 in dielectric layer 182 may include the dopant from the angled ion implantations (shaded surface of first portion 252), e.g., argon, in dielectric layer 182.

As shown in FIGS. 14-17, dielectric sub-layers 136, 190 of dielectric layer 182 about cavity 180 cover any conductor, e.g., any conductive wire 196 in the first metal layer or any conductive contact 148 in the local interconnect layer.

Although not shown, it will be understood that cavities 180 can take a variety of laterally elongated forms. For example, openings 200 may be etched as laterally elongated openings above transistor gate 120. That is, rather than simple vertical openings, openings 200 have a length, e.g., just short of that of a transistor gate 120 that they parallel. In one example (not shown), a portion of cavity 180 can be arranged in a laterally disposed T-shape, i.e., in a T-shape laid out horizontally into and out of the page. In other example, cavity 180 can have varying widths along a length thereof.

As will be recognized, semiconductor device 250 can be used to form a variety of devices such as a radio frequency semiconductor-on-insulator (RFSOI) switch, a low amplitude amplifier, a power amplifier, etc. In an RFSOI switch embodiment, transistor 116 includes source/drain regions 118 in a semiconductor-on-insulator (SOI) layer 112 of an SOI substrate 106 and gate 120 over SOI layer 112 with gate 120 having gate body 122.

Embodiments of the disclosure provide various technical and commercial advantages, examples of which are discussed herein. Use of cavity (air gap) over a transistor gate according to the various embodiments of the disclosure provides a mechanism to reduce off-capacitance and on-resistance of any device using it by controlling one of the main contributors of intrinsic FET capacitance: the effective dielectric constant of the local interconnect layer and the first metal layer. The negative sloped sidewall places a wider portion of the cavity closer to the gate, which reduces parasitic and off-state capacitance and improves RF performance. Embodiments of the disclosure integrate fully with existing cavity, i.e., air gap, formation processes.

In the structures and method described above, a semiconductor material refers to a material whose conducting properties can be altered by doping with an impurity. Semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped with a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region. Furthermore, when a semiconductor region or layer is described as being at a higher conductivity level than another semiconductor region or layer, it is more conductive (less resistive) than the other semiconductor region or layer; whereas, when a semiconductor region or layer is described as being at a lower conductivity level than another semiconductor region or layer, it is less conductive (more resistive) than that other semiconductor region or layer.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A semiconductor device, comprising:
a transistor including a gate;
a dielectric layer over the gate; and
a cavity in the dielectric layer above the gate, a first portion of the cavity over the gate having a negative sloped sidewall in the dielectric layer.

2. The semiconductor device of claim 1, wherein the first portion of the cavity in the dielectric layer has a first width at a first height and a second width less than the first width at a second height, wherein the first height is closer to the gate than the second height and the negative sloped sidewall extends between the first height and the second height.

3. The semiconductor device of claim 2, wherein the cavity has a second portion in the dielectric layer over and contiguous with the first portion, the second portion having the second width at the second height and a third width larger than the second width at a third height, wherein the second height is between the first height and the third height.

4. The semiconductor device of claim 3, wherein the cavity has a third portion in the dielectric layer under and contiguous with the first portion, the third portion having a fourth width smaller than the first width at a fourth height below the first height.

5. The semiconductor device of claim 2, wherein the cavity has a second portion in the dielectric layer under and coupled to the first portion, the second portion having a third width at a third height, the third width smaller than the first width.

6. The semiconductor device of claim 1, wherein the first portion has a trapezoidal cross-section having a first width at a lower end of the first portion and a second width smaller than the first width at an upper end of the first portion.

7. The semiconductor device of claim 6, wherein the cavity further includes a second portion in the dielectric layer having a trapezoidal cross-section having the second width at a lower end of the second portion contiguous with the upper end of the first portion and a third width larger than the second width at an upper end of the second portion.

8. The semiconductor device of claim 7, wherein the cavity further includes a third portion in the dielectric layer having a rectangular cross-section having a fourth width smaller than the first width of the first portion and contiguous with the lower end of the first portion.

9. The semiconductor device of claim 1, wherein the negative sloped sidewall in the dielectric layer includes a dopant in the dielectric layer.

10. The semiconductor device of claim 1, wherein a portion of the dielectric layer is positioned between the cavity and the gate.

11. The semiconductor device of claim 1, wherein the cavity includes one of a gas and a vacuum therein.

12. A semiconductor device, comprising:
a transistor including a gate;
a dielectric layer over the gate; and
a cavity in the dielectric layer above the gate, the cavity including:
a first portion having a trapezoidal cross-section having a first width at a lower end of the first portion and a second width smaller than the first width at an upper end of the first portion, and
a second portion having a trapezoidal cross-section having the second width at a lower end of the second portion and contiguous with the upper end of the first portion and a third width larger than the second width at an upper end of the second portion.

13. The semiconductor device of claim 12, wherein the cavity further includes a third portion in the dielectric layer having a rectangular cross-section having a fourth width smaller than the first width of the first portion and contiguous with the lower end of the first portion.

14. The semiconductor device of claim 12, wherein the dielectric layer defining the first portion of the cavity includes a dopant in the dielectric layer.

15. The semiconductor device of claim 12, wherein the cavity includes one of a gas and a vacuum therein.

16. A method of forming a cavity for a semiconductor device, the method comprising:
forming a dielectric layer over a transistor including a gate; and
forming a cavity in the dielectric layer above the gate, a first portion of the cavity over the gate having a negative sloped sidewall.

17. The method of claim 16, wherein forming the dielectric layer and the cavity includes:
forming a first dielectric sub-layer over the gate;
forming a damaged area in the first dielectric sub-layer over the gate, the damaged area having a portion over the gate having a negative sloped sidewall;
forming a second dielectric sub-layer over the first dielectric sub-layer to form the dielectric layer;
forming an opening into the dielectric layer, the opening extending into the damaged area; and
forming the cavity over the gate by depositing a capping layer to seal the opening.

18. The method of claim 17, wherein forming the damaged area in the first dielectric sub-layer over the gate includes performing an angled ion implantation including:
first ion implanting a dopant at a first angle into the first dielectric sub-layer over the gate, the first angle matching a first side of the negative sloped sidewall; and
second ion implanting the dopant at a second angle into the first dielectric sub-layer over the gate, the second angle matching a second side of the negative sloped sidewall.

19. The method of claim 18, wherein forming the damaged area further includes third ion implanting the dopant at an angle perpendicular to the first dielectric sub-layer over the gate.

20. The method of claim 16, wherein forming the first portion of the cavity includes forming the first portion of the cavity to have a first section having a first width and a second section having a second width less than the first width, wherein the first section is closer to the gate than the second section and the negative sloped sidewall connects the first section and the second section.
